(19) United States
(12) Patent Application Publication
(10) Pub. No.: US 2026/0147018 A1
(43) Pub. Date: May 28, 2026

(54) MULTI-SENSOR PROBES WITH CONTINUOUS TIME PATH

(71) Applicant: Tektronix, Inc., Beaverton, OR (US)

(72) Inventor: Mark A. Norris, Louisville, CO (US)

(73) Assignee: Tektronix, Inc., Beaverton, OR (US)

(21) Appl. No.: 19/388,974

(22) Filed: Nov. 13, 2025

Related U.S. Application Data
(60) Provisional application No. 63/719,888, filed on Nov. 13, 2024.

(51) Int. Cl. G01R 13/02

(52) U.S. Cl. CPC G01R 13/0218

(57) ABSTRACT

A test and measurement probe device is disclosed. In some implementations, the device may include one or more sensors. In addition, the device may include a plurality of analog signal paths, each analog signal path connected to one of the one or more sensors. The device may include an adjustable gain element within each analog signal path. Moreover, the device may include a combiner to combine the output of each adjustable gain element together to produce a probe output signal. Also, the device may include a digital path including a processor, where the processor is configured to compute a gain value for at least one adjustable gain element.

### CROSS-REFERENCE TO RELATED APPLICATION

This application is a non-provisional of, and claims priority from, U.S. Provisional Pat. App. No. 63/719,888, filed Nov. 13, 2024, which is hereby incorporated by reference in its entirety into this application.

### TECHNICAL FIELD

This disclosure relates to test and measurement systems, and more particularly to test and measurement probes.

### BACKGROUND

Users of test and measurement instruments, such as oscilloscopes, typically use a test and measurement probe as the interface between the test and measurement instrument and a device under test (DUT). Test and measurement probes are designed for particular measurement applications. For example, voltage probes are designed for measuring a voltage signal in a DUT. Voltage probes can be further sub-categorized into probes designed for measuring high voltages versus those designed for measuring low voltages, probes designed to measure single-ended signals versus probes designed to measure differential signals, etc. Likewise, current probes are designed for measuring a current signal in a DUT. Current probes can be further sub-categorized into supported ranges of minimum and maximum currents to be measured, different bandwidths of the measured current signal, single-ended versus differential, etc. Conventional probes typically use a single sensor with a single analog signal path.

### BRIEF DESCRIPTION OF THE DRAWINGS

FIG. 1 is a block diagram of a test system including a test and measurement probe and a test and measurement instrument.

FIG. 2 is a block diagram of a probe according to some embodiments of the disclosure.

FIG. 3 is a block diagram of a probe according to some embodiments of the disclosure.

FIG. 4 is a block diagram of a probe according to some embodiments of the disclosure.

FIG. 5 is a diagram of a model for a probe according to some embodiments of the disclosure.

FIG. 6 is a diagram of a model for a probe according to some embodiments of the disclosure.

FIG. 7 is a frequency response plot using a numerical example of a probe according to some embodiments of the disclosure.

FIG. 8 is a diagram of a model for a combined analog-to-digital converter according to some embodiments of the disclosure.

### DETAILED DESCRIPTION

Embodiments of the disclosure generally include test and measurement probes, such as oscilloscope probes, having multiple sensors. Embodiments of the disclosure enhance probe output by optimally merging readings from multiple sensors or analog paths.

In probes that utilize or are augmented with two or more sensors or analog signal paths, the embodiments of the disclosure generally combine the output of these sensors or paths in a fast analog signal processing path to maximize the accuracy and/or improve the bandwidth of the probe output. Pre-determined mergings are used when sensor characteristics are known, and dynamic adjustments are made for changes like gain.

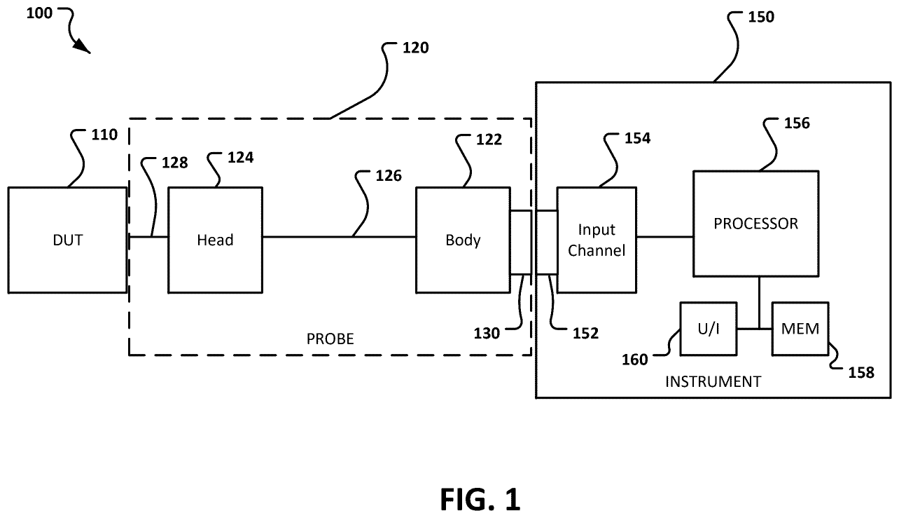

FIG. 1 is a block diagram of an example test system 100 for testing a device under test (DUT) 110, according to embodiments of the disclosure. Test system 100 includes a test and measurement instrument 150, and a test and measurement probe 120 coupled between the test and measurement instrument and the DUT.

The DUT may be any type of device that has voltage or current signals to be measured by the test system, i.e. by the combination of the probe 120 and the instrument 150. In some examples, the DUT may simply be a current-carrying conductor, such as a wire, or a trace on a printed circuit board (PCB).

The instrument 150 generally includes an input connector 152 to electromechanically couple to the probe 120. The input connector provides an interface between the probe and the instrument, and generally includes an analog input signal path, such as a BNC connector, to receive an analog electrical output signal from the probe representative of the signal being measured in the DUT. But, in some examples, the input connector may also include one or more additional analog and/or digital connections to, for example, provide power to the probe 120, control and communication between the probe and the instrument, and other functions. In some examples, the input signal to the instrument is provided digitally by the probe.

The input signal from probe 120 is typically routed through the input connector 152 to input channel circuitry 154. Input channel circuitry 154 may include filters, attenuators, amplifiers, offset control, and other signal conditioning circuitry, as well as one or more analog-to-digital converters (ADCs) to convert the analog input signal from the probe into an acquired digital waveform. Acquisition of the input signal may be controlled by one or more processors 156. The one or more processors 156 may perform triggering functions, further processing of the acquired digital waveform, such as through digital signal processing (DSP), etc.

The one or more processors 156 may operate according to instructions stored in a memory 158, which may also store one or more acquired waveforms. The instrument 150 also includes a user interface 160. The user interface can include input interfaces such as keyboards, mice, touchscreen, a programmatic interface, etc., to allow a user to control and operate the instrument, and the connected probe 120. The user interface can also include output interfaces, such as a display, to for example display an acquired waveform, such as the measured signal from the DUT.

The probe 120, according to embodiments of the disclosure, includes a probe body 122, a probe head or sensor head 124, which is separate from the probe body, and a connection 126 between the probe body and the sensor head. The probe body 122 is enclosed in a housing. The probe body includes an output connector 130, which interfaces with and connects to input connector 152 of the instrument 150 in order to output the electrical measurement signal to an input of the instrument 150. Thus, in operation, the probe body 122 is physically near the input connector 152 of the instrument 150. The connection 126 is typically relatively long and flexible, such as a cable, to allow the sensor head 124 to be conveniently located physically close to the DUT.

The sensor head 124 has a coupling interface 128 to the DUT. According to some embodiments of the disclosure, in which the probe is used for measuring a voltage signal in the DUT, the coupling interface 128 may be, for example, a pair of leads to be connected, either permanently, or by temporary physical contact, to a voltage in the DUT to be measured, e.g. between two circuit nodes in the DUT. According to other embodiments of the disclosure, in which the probe is used for measuring a current signal in the DUT, the coupling interface 128 may be, for example, a sensor that wraps around a current-carrying conductor in the DUT, such as a Rogowski coil, for example.

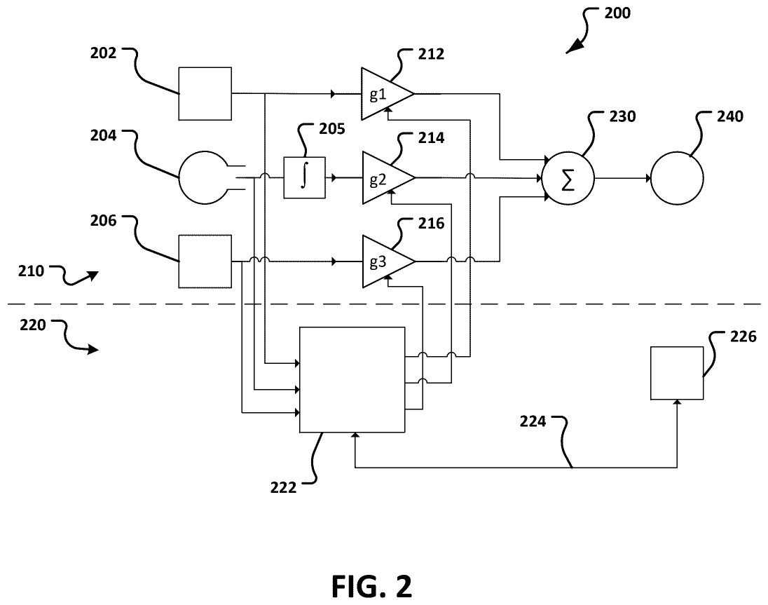

FIG. 2 is a block diagram of an example test and measurement probe 200, according to embodiments of the disclosure. Probe 200 may be an example of the test and measurement probe 120 shown in FIG. 1. Generally, according to embodiments of the disclosure, the probe 200 includes multiple sensors to extend the bandwidth of the probe, and to improve the Signal-to-Noise Ratio (SNR) of the probe.

Probe 200 includes an analog signal path 210 and a digital path 220. The analog signal path 210 includes a plurality of sensors 202, 204, 206. The sensors 202, 204, 206 may be different types of sensors, as represented by the different shapes used in FIG. 2. For example, the sensors may sense voltage, current, magnetic field, electrical field, light, temperature, humidity, pressure, etc. Generally, each sensor is structured to detect a physical quantity, such as current, and convert that physical quantity into an electrical signal that can be further processed by the probe 200, and conveyed to a connected test and measurement instrument, such as instrument 150 in FIG. 1, for display and/or analysis.

In the analog signal path 210, each sensor 202, 204, 206 has, or is connected to a respective gain 212, 214, 216. Some sensors may have their output analog signal pass through additional signal processing prior to, or in some case after, the sensor's respective gain stage. For example, as shown in FIG. 2, the output of sensor 204, which may be a Rogowski coil current sensor in this example, may pass through an integrator stage 205 prior to the gain stage 214. The outputs of each gain stage 212, 214, 216 are then combined together, for example at summation block 230. The combined output signal is transmitted to a probe output 240. Probe output 240 may be an example of the probe output connector 130 shown in FIG. 1.

In the digital path 220, the output signals of each of the sensors 202, 204, 206 are input to a digital processor 222. The processor 222 may comprise a microprocessor, a microcontroller, a CPU, an FPGA, an ASIC, etc. The processor 222 is configured to compute the gain for each of the gain stages 212, 214, 216 for each respective sensor 202, 204, 206. The processor sets each gain in the analog signal path 210: gain g1 of gain stage 212 for sensor 202; gain g2 for gain stage 214 for sensor 204; and gain g3 for gain stage 216 for sensor 206. The processor 222 may have a digital communication path 224, to a digital input/output port 226, which may allow it to communicate with a connected test and measurement instrument. Digital I/O port 226 may be included in the probe output connector 130 shown in FIG. 1.

Generally, the analog signal path 210 may be considered a “fast” signal path through the probe 200, while the digital path 220 may be considered relatively “slow.” The analog signal path can pass the output signals of the sensors 202, 204, 206 much more quickly than the digital path 220 and processor 222 can process those signals. However, by having the digital path 220 compute the gains for each sensor's respective gain stage, the analog signal path 210 is able to combine the sensors' outputs in an optimal way to maximize the SNR. This general analog and digital split path structure of probe 200 can be employed in a number of different applications, according to various embodiments of this disclosure.

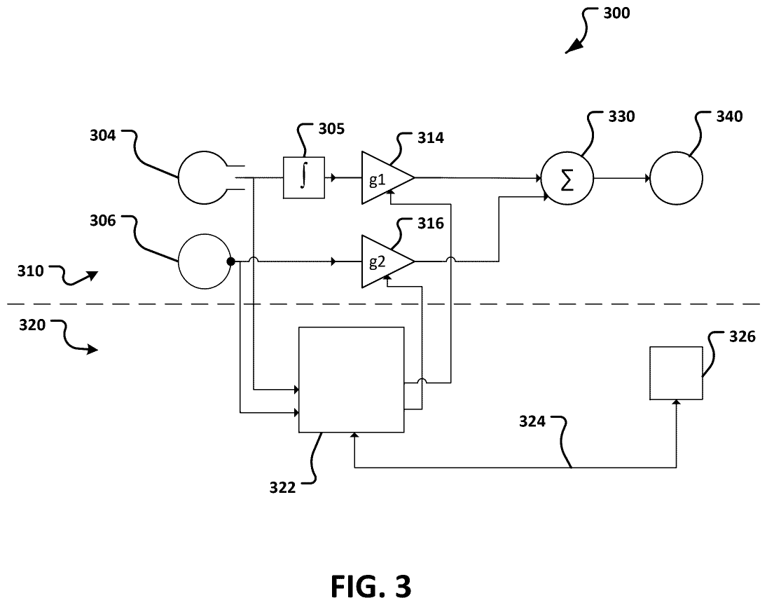

FIG. 3 is a block diagram of a probe 300 according to some embodiments of this disclosure. In this example, probe 300 is a current probe. Probe 300 is similar to probe 200 of FIG. 2 by having an analog path 310 and a digital path 320. There are two sensors in the analog path 310, sensor 304 and sensor 306. Sensor 306 may be a clamp-on current sensor. Sensor 306 has, or is connected to gain stage 316, having a gain g2 computed and set by processor 322 in the digital path 320. Sensor 304 has, or is connected to gain stage 314, having a gain g1 computed and set by processor 322 in the digital path 320. As shown in FIG. 3, the output of sensor 304 may undergo additional analog stages, such as through integrator stage 305, prior to gain stage 314. The outputs of the gain stages 314 and 316 are combined at block 330 and the combined signal may be output from the probe at 340. According to some embodiments, the sensor 306 may in fact represent an existing clamp-on current probe, such as a Tektronix TCP0030A Current Probe, for example. As known, a clamp-on current probe sensor senses current through a current-carrying conductor in a DUT by fully encircling the conductor. The bandwidth of the existing clamp-on current probe, represented by sensor 306, may be extended by augmenting the sensor 306 with the additional sensor 304 in the analog signal path 310. The additional sensor 304 may be, for example, a small, high-frequency sensor that does not encircle the current-carrying conductor. The sensor 304 can be designed and optimized for high-frequency current measurements. The gains g1 and g2 of the gain stages 314 and 316 can be computed by the processor 322 to optimally combine the outputs of sensors 304 and 306 for combination at summation block 330.

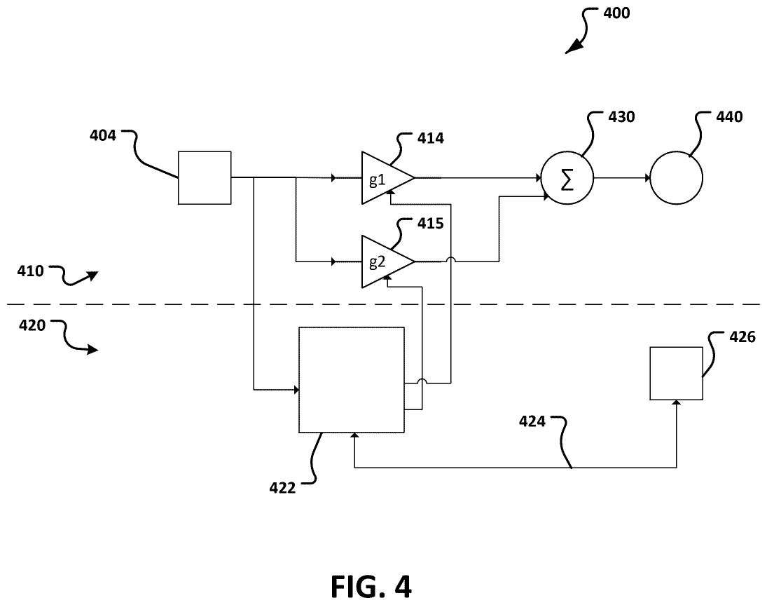

According to other embodiments of this disclosure, a probe may have a single sensor, but multiple analog output paths from the single sensor, the multiple analog paths having different gains. FIG. 4 is a block diagram of a probe 400 having a single sensor with multiple analog output paths, according to some embodiments of this disclosure.

As shown in FIG. 4, the probe 400 has an analog signal path portion 410, and a digital signal path portion 420. The analog portion includes a single sensor 404, which may be any type of sensor, including a voltage sensor or a current sensor in this example. The analog output of the sensor 404 is split into two analog paths which are fed into two different amplifiers 414, 415. Each of these two analog paths and its associated amplifier is optimized for different frequency ranges. For example, the analog path for amplifier 414 may be optimized for low frequencies, and amplifier 414 may be a chopper stabilized DC and low frequency (LF) amplifier, while amplifier 416 may be a low noise amplifier (LNA) for high frequencies and the analog path for amplifier 416 may be optimized for high frequencies. The analog output of sensor 404 is also split and input to processor 422 in the digital path 420. The processor 422 computes and sets the gain g1 for the low-frequency-optimized amplifier 414, and the gain g2 for the high-frequency-optimized amplifier 415. The amplified signals in the low-frequency-optimized analog path and the high-frequency-optimized analog path are recombined at the summation block 430, and then the combined signal may be output from the probe 400 at probe output 440.

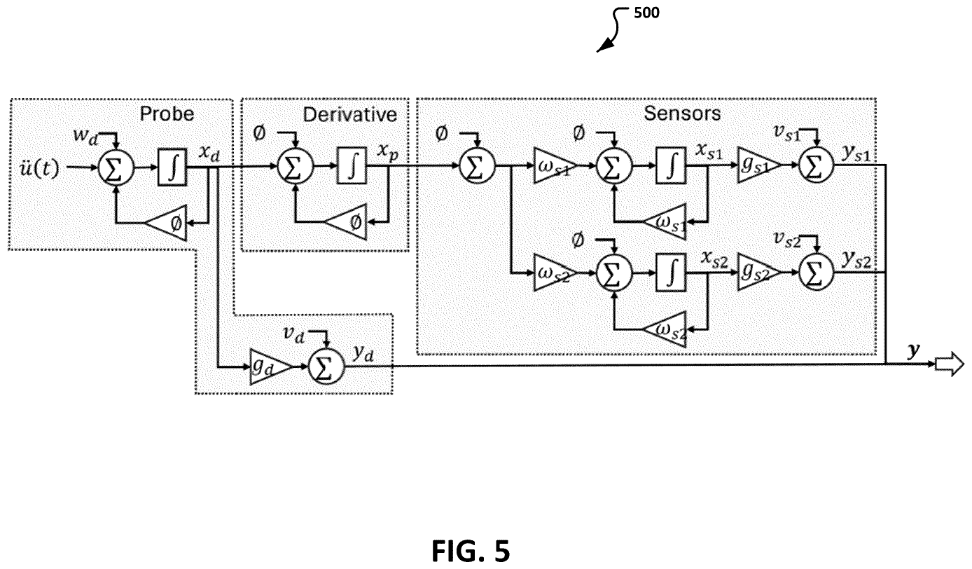

FIG. 5 illustrates a model 500 of a signal through a probe, such as probes 200, 300, 400, according to embodiments of this disclosure. In the model 500 of FIG. 5, xₚ, is the actual measurement of the probe. The derivative, x_{d}, feeds into a perfect integrator of the probe measurement, thus a derivative. Values xₛ₁ and xₛ₂ are from two different sensors with bandwidths ωₛ₁ and ωₛ₂. In the model, all process noise, Q, is modeled as coming into the input so it hits the derivative. The noise propagates into additional stages. The input ü(t) is set to zero for the purposes of modeling as it is unknown.

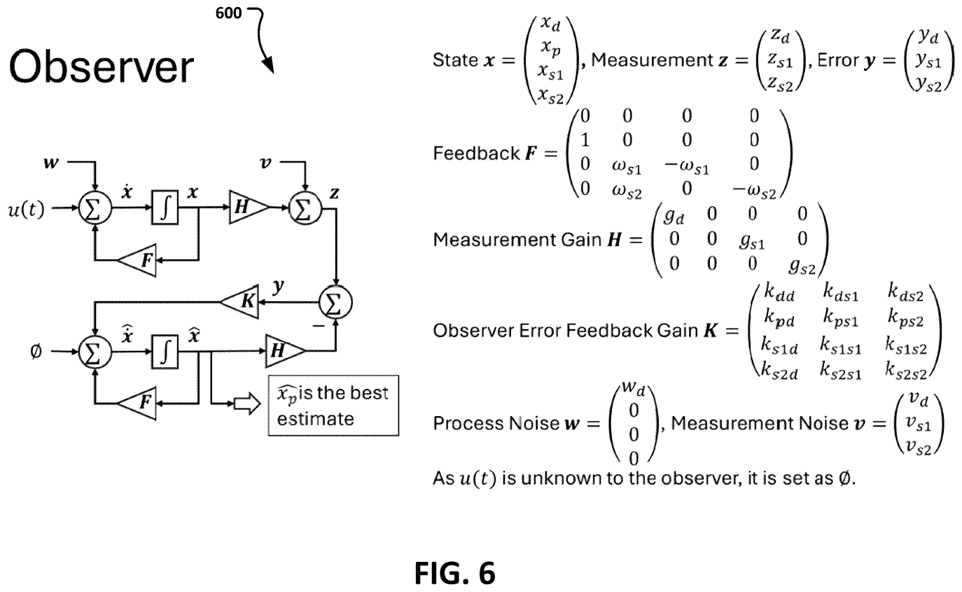

FIG. 6 illustrates a model 600 of observer error in a probe, such as probes 200, 300, 400, according to embodiments of this disclosure. In the model 600 of FIG. 6, there is a state vector, x, a measurement vector, z, and an error vector, y:

$$x = ( \begin{matrix}{x}_{d} \\ {x}_{p} \\ {x}_{s 1} \\ {x}_{s 2}\end{matrix} ) z = ( \begin{matrix}{z}_{d} \\ {z}_{s 1} \\ {z}_{s 2}\end{matrix} ) y = ( \begin{matrix}{y}_{d} \\ {y}_{s 1} \\ {y}_{s 2}\end{matrix} ) \qquad ( 1 )$$

Feedback matrix F is:

$$F = ( \begin{matrix}0 & 0 & 0 & 0 \\ 1 & 0 & 0 & 0 \\ 0 & {ω}_{s 1} & - {ω}_{s 1} & 0 \\ 0 & {ω}_{s 2} & 0 & - {ω}_{s 2}\end{matrix} ) \qquad ( 2 )$$

Measurement Gain matrix H is:

$$H = ( \begin{matrix}{g}_{d} & 0 & 0 & 0 \\ 0 & 0 & {g}_{s 1} & 0 \\ 0 & 0 & 0 & {g}_{s 2}\end{matrix} ) \qquad ( 3 )$$

Observer Error Feedback Gain matrix K is:

$$K = ( \begin{matrix}{k}_{dd} & {k}_{ds 1} & {k}_{ds 2} \\ {k}_{pd} & {k}_{p s 1} & {k}_{p s 2} \\ {k}_{s 1 d} & {k}_{s 1 s 1} & {k}_{s 1 s 2} \\ {k}_{s 2 d} & {k}_{s 2 s 1} & {k}_{s 2 s 2}\end{matrix} ) \qquad ( 4 )$$

Process Noise vector w is:

$$w = ( \begin{matrix}{w}_{d} \\ 0 \\ 0 \\ 0\end{matrix} ) \qquad ( 5 )$$

And, Measurement Noise vector v is:

$$v = ( \begin{matrix}{v}_{d} \\ {v}_{s 1} \\ {v}_{s 2}\end{matrix} ) \qquad ( 6 )$$

As u(t) is unknown to the observer, it is set as φ.

According to embodiments of the disclosure, a continuous time Kalman filter may be utilized by observing the following set of equations:

$$K = P \cdot {H}^{T} \cdot {R}^{- 1} \qquad ( 7 )$$

$$\dot{P} = F \cdot P + P \cdot {F}^{T} + Q - K \cdot R \cdot {K}^{T} \qquad ( 8 )$$

### Where:

$$Q = diag ( {w}^{2} ) , and R = diag ( {r}^{2} )$$

### Substituting:

$$\dot{P} = F \cdot P + P \cdot {F}^{T} + Q - P \cdot {H}^{T} \cdot {R}^{- 1} \cdot R \cdot {R}^{- {1}^{T}} \cdot H \cdot {P}^{T} \qquad ( 9 )$$

$$= F \cdot P + P \cdot {F}^{T} + Q - P \cdot {H}^{T} \cdot {R}^{- {1}^{T}} \cdot H \cdot {P}^{T} \qquad ( 10 )$$

Which is estimated dynamically along with X.

Or, this is the algebraic Riccati equation (noting that P is symmetric, as are Q and R), for which there exist good solvers to solve X=0 for a Steady State Kalman Filter.

$$Riccati Equation : 0 = {A}^{T} \cdot X + X \cdot A - X \cdot G \cdot X + Q ,$$

$$where X = P , A = {F}^{T} , G = {H}^{T} \cdot {R}^{- 1} \cdot H$$

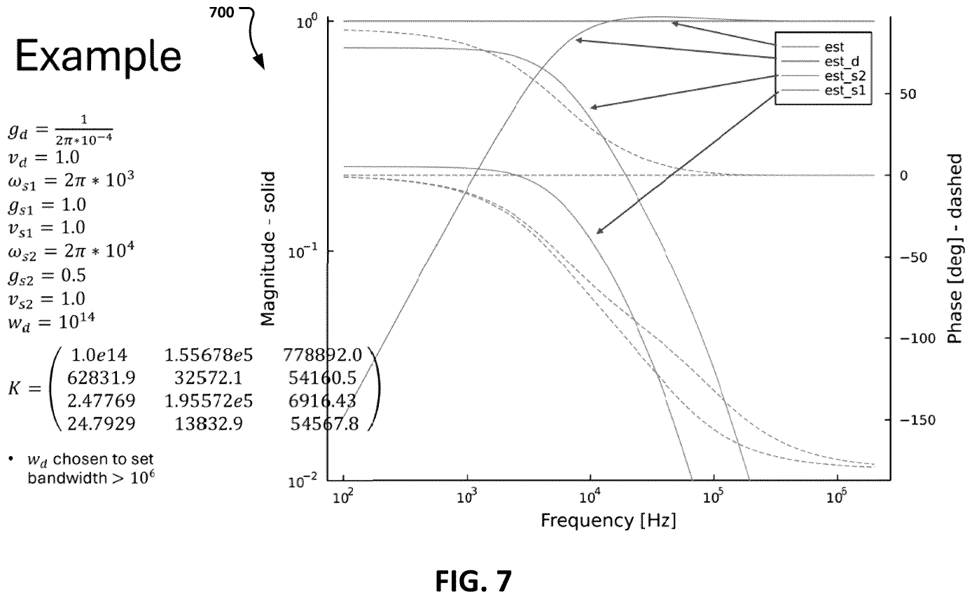

FIG. 7 shows a numerical example of computing the observer error feedback gain matrix, K, and a plot 700 of the frequency response of a probe with multiple sensors with gains, according to embodiments of the disclosure. The probe model, such as the model 500, should be accurate for best results in these calculations. Also, it can be observed that the derivative state grows exponentially, so this may need scaling or be band limited to limit the actual state variable. Such scaling can be used to keep the K matrix uniform.

According to embodiments of the disclosure, a probe can use overlapped frequency ranges for the multiple sensors to determine the relative gains of the sensors for optimal combination of the sensor signals. That is, embodiments can use a band of frequency overlap to calibrate the gain of one or more sensors relative to another “master” sensor. As an example, this approach can be used when an existing single-sensor probe, such as an existing clamp-on current sensor as discussed above, is augmented with one or more additional high-frequency pickup coils that are too small to fully wrap around a conductor. The DC/LF current probe/sensor measures the low frequency with gain accuracy. Within the overlapped frequency range, the higher frequency sensor(s) measure the same frequency range to compute the HF sensor gain as the HF sensors' current measurements are dependent on the geometry of the sensor relative to the conductor.

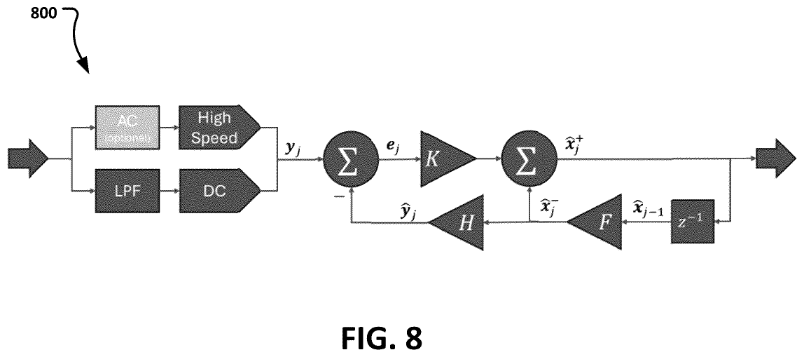

FIG. 8 shows a model 800 of a split-path architecture for a composite analog-to-digital converter (ADC) that combines the outputs of a high-resolution DC/low-bandwidth ADC and a high-speed ADC. The model 800 illustrates that the same approach for dynamic filtering discussed above for continuous time can also be used in discrete time.

U.S. Pat. App. Pub. No. 2025/0258202, titled “CORRECTED CURRENT MEASUREMENTS USING MULTIPLE MAGNETIC FIELD SENSORS,” the contents of which are hereby incorporated by reference, discloses techniques for improving measurements using multiple sensors. Embodiments of this disclosure complement those techniques, and additionally reject external disturbances. Some embodiments of this disclosure use a Kalman Filter to minimize the noise, but other techniques may be utilized according to other embodiments.

U.S. Pat. App. Pub. No. 2025/0258202 discloses a current probe that, with reasonable accuracy, measures the current flowing through a trace on a PCB over a ground plane without wrapping the probe around the trace. Instead, the probe is placed on top of the trace, and it measures the current without wrapping around. However, one complication is that the gain of the probe varies with the mechanical parameters of the DUT, for example, the width of the trace and the height of the trace above the ground plane. A solution is to have multiple small current sensors in a known physical configuration relative to one another, and then solving for the current and the mechanical parameters simultaneously. One can solve for the gain from the B-field measurement on one or more sensors. This solving can be done slowly. Then, the computed gain can be quickly applied to measure the current. Since solving for the gain can be done slowly, this computation can be accomplished by using a processor in a “slow” digital path of the probe, similar to the digital paths 220, 320, 420 described above. The computed gains can be set in a “fast” analog path of the probe.

The Appendix of U.S. Provisional Pat. App. No. 63/719,888 describes additional configurations of a probe having multiple current sensors for one-sided current measurement of PCB traces.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

What is claimed is:

1. A test and measurement probe, comprising:
one or more sensors;
a plurality of analog signal paths, each analog signal path connected to one of the one or more sensors;
an adjustable gain element within each analog signal path;
a combiner to combine the output of each adjustable gain element together to produce a probe output signal; and
a digital path including a processor, wherein the processor is configured to compute a gain value for at least one adjustable gain element.

2. The test and measurement probe of claim 1, wherein the processor is further configured to adjust the gain of the at least one adjustable gain element to the computed gain value.

3. The test and measurement probe of claim 1, wherein an output signal of the one or more sensors is connected to an input of the processor, and the processor is configured to compute the gain value for the at least one adjustable gain element based on the output signal of the one or more sensors.

4. The test and measurement probe of claim 1, wherein the processor is configured to compute a gain value for each adjustable gain element.

5. The test and measurement probe of claim 4, wherein the processor is further configured to adjust the gain of each adjustable gain element to the computed gain value for each adjustable gain element.

6. The test and measurement probe of claim 5, wherein the processor is further configured to compute the gain value for each adjustable gain element to optimize a signal-to-noise ratio (SNR) of the probe output signal.

7. The test and measurement probe of claim 5, wherein the processor is further configured to compute the gain value for each adjustable gain element to extend a bandwidth of the probe.

8. The test and measurement probe of claim 1, wherein the combiner comprises a summing element.

9. The test and measurement probe of claim 1, further comprising an output connector for outputting the probe output signal to a test and measurement instrument.

10. The test and measurement probe of claim 1, further comprising a digital communication port connected to the processor.

11. The test and measurement probe of claim 1, further comprising an analog processing stage within at least one of the analog signal paths.

12. The test and measurement probe of claim 11, wherein the analog processing stage comprises an integrator.

13. The test and measurement probe of claim 1, wherein each of the one or more sensors comprises a sensor selected from the group consisting of a voltage sensor, a current sensor, a magnetic field sensor, an electric field sensor, and a light sensor.

14. The test and measurement probe of claim 1, wherein:
the one or more sensors comprise a first sensor and a second sensor;
the first sensor is connected to a first analog signal path having a first adjustable gain element, and to a first input of the processor;
the second sensor is connected to a second analog signal path having a second adjustable gain element, and to a second input of the processor; and
the processor is configured to compute and adjust the gain values of the first and second adjustable gain elements.

15. The test and measurement probe of claim 14, wherein the first sensor is a direct current and low frequency (DC/LF) sensor, and the second sensor is a high frequency (HF) sensor.

16. The test and measurement probe of claim 14, wherein the first sensor and the second sensor have bandwidths with a partially overlapping frequency range.

17. The test and measurement probe of claim 1, wherein:
the one or more sensors comprise a single sensor,
the single sensor is connected to a first analog signal path having a first adjustable gain element, to a second analog signal path having a second adjustable gain element, and to an input of the processor.

18. The test and measurement probe of claim 17, wherein the first adjustable gain element comprises a high-resolution, low-frequency amplifier, and the second adjustable gain element comprises a high-frequency low noise amplifier.

19. The test and measurement probe of claim 1, wherein the processor is configured to compute the gain value in continuous time.

20. The test and measurement probe of claim 1, wherein the processor is further configured to dynamically compute a Kalman filter.
